(19) United States
(12) Patent Application Publication
(10) Pub. No.: US 2018/0310400 A1
(43) Pub. Date: Oct. 25, 2018

(54) Dust Cover for Electrical Leads

(71) Applicant: The ESAB Group Inc., Florence, SC (US)

(72) Inventors: Arivukkarasu MANAVALAN, Baltimore, MD (US); Pranav SANGHAVI, Ellicott City, MD (US); Lee Roy MANTELL, Essex, MD (US)

(21) Appl. No.: 15/960,593

(22) Filed: Apr. 24, 2018

Related U.S. Application Data
(63) Continuation of application No. PCT/IB2016/056574, filed on Nov. 1, 2016.

(30) Foreign Application Priority Data
Nov. 6, 2015 (IN) 3646/DEL/2015

(51) Int. Cl. H05K 1/02; H05K 3/30; H05K 3/34

(52) U.S. Cl. CPC H05K 1/0256; H05K 3/306; H05K 2201/10977; H05K 3/3447; H05K 2201/0133; H05K 3/301

(57) ABSTRACT

A dust cover for mitigating electrical arcing between electrical leads of a powered device, the dust cover including a unitary body formed of an elastic, electrically insulating material, the unitary body having a closed top portion and an open bottom portion, the open bottom portion defining a hollow interior chamber, the closed top portion having a slit extending therethrough from an upper surface of the unitary body to the interior chamber for accepting the electrical leads.

### CROSS-REFERENCE TO RELATED APPLICATIONS

This application is a Continuation of PCT/IB2016/056574 filed on Nov. 1, 2016, which PCT claims the benefit of Indian Patent Application No. 3646/DEL/2015, filed Nov. 6, 2015, both of which are incorporated by reference herein in their entirety.

### FIELD OF THE DISCLOSURE

The disclosure relates generally to the field of welding machines, and more particularly to a dust cover for preventing electrical arcing between electrical power leads in welding machines.

### BACKGROUND OF THE DISCLOSURE

Welding machines are often provided with circuitry that includes electrically powered devices for facilitating automatic and/or manual operation of various welding machine components. Such powered devices typically receive electrical power via electrically conductive leads that are soldered to printed circuit boards (PCBs). A single powered device may include a plurality of electrical leads that are held at different voltage potentials.

The leads of powered devices in welding machines are known to be susceptible to electrical arcing caused by metallic particulate (“metal dust”) that is often prevalent in workshops, manufacturing facilities, and other environments in which welding machines are used. Metal dust may accumulate between the electrical leads of powered devices and may establish electrically-conductive pathways through which electricity may propagate.

Various covers and enclosures have been developed for shielding electrical leads of powered devices from metal dust to mitigate electrical arcing. However, due to normal manufacturing tolerances, there is typically some amount of space between the interior surfaces of such covers and the surfaces of the electrical leads which they are meant to protect. Metal dust may infiltrate these spaces and cause electrical arcing.

It is with respect to these and other considerations that the present improvements may be useful.

### SUMMARY

This Summary is provided to introduce a selection of concepts in a simplified form that are further described below in the Detailed Description. This Summary is not intended to identify key features or essential features of the claimed subject matter, nor is it intended as an aid in determining the scope of the claimed subject matter.

An exemplary embodiment of dust cover for mitigating electrical arcing between electrical leads of a powered device may include a unitary body formed of an elastic, electrically insulating material, the unitary body having a closed top portion, an open bottom portion, a hollow interior chamber extending from the open bottom portion and a slit formed in the closed top portion for passing the electrical leads therethrough, the slit being in communication with the hollow interior chamber.

The dust cover may have a generally rectangular shape. In addition, the dust cover may be made from one of a rubber, a silicone, or a plastic.

The slit may extend from an upper surface of the dust cover to the hollow interior chamber. In use, the open bottom portion of the dust cover may be operatively mounted onto a printed circuit board (PCB). In this manner, the dust cover may be positioned between the powered device and the PCB. In an uncompressed state, the height of the dust cover may be greater than a vertical distance between a bottom surface of the powered device and a front side of the PCB so that the dust cover is compressed between the powered device and the PCB. The closed top portion of the dust cover may be pressed against the bottom surface of the powered device and the front side of the PCB thereby establishing a seal between the dust cover and the powered device and between the dust cover and the PCB.

The electrical leads may extend from the PCB through the open bottom portion, the hollow interior chamber, and the slit for connecting to the powered device. The electrical leads may also extend through apertures formed in the PCB.

The slit may be self-sealing. The slit may be formed by cutting the elastic, electrically insulating material.

The dust cover may further include a tapered side wall having an upper end and a lower end adjacent the open bottom portion, wherein the lower end has a thickness that is greater than a thickness of the upper end. The lower end adjacent the open bottom portion provides for an increased area for contacting a printed circuit board (PCB).

Another exemplary embodiment of a dust cover for mitigating electrical arcing between electrical leads of a powered device may include a unitary body formed of an elastic, electrically insulating material, the unitary body having a closed top portion, an open bottom portion, a hollow interior chamber extending from the open bottom portion, and a plurality of discrete, spaced-apart passageways for passing the electrical leads therethrough, wherein the plurality of discrete, spaced-apart passageways are in communication with the hollow interior chamber.

The dust cover may have a generally rectangular shape. In addition, the dust cover may be made from one of a rubber, a silicone, or a plastic.

The plurality of discrete, spaced-apart passageways may extend from an upper surface of the dust cover to the hollow interior chamber. The open bottom portion of the dust cover may be operatively mounted onto a printed circuit board (PCB) so that the dust cover is positioned between the powered device and the PCB. In an uncompressed state, the height of the dust cover may be greater than a vertical distance between a bottom surface of the powered device and a front side of the PCB so that the dust cover is compressed between the powered device and the PCB. The closed top portion of the dust cover may be pressed against the bottom surface of the powered device and the front side of the PCB thereby establishing a seal between the dust cover and the powered device and between the dust cover and the PCB. The electrical leads may extend from the PCB through the open bottom portion, the hollow interior chamber, and the slit for connecting to the powered device.

The dust cover may further include a tapered side wall having an upper end and a lower end adjacent the open bottom portion, wherein the lower end has a thickness that is greater than a thickness of the upper end. The lower end adjacent the open bottom portion provides for an increased area for contacting a printed circuit board (PCB).

### BRIEF DESCRIPTION OF THE DRAWINGS

FIG. 1 is an isometric view illustrating an embodiment of a dust cover in accordance with the present disclosure.

FIG. 2a is a side cross sectional view illustrating the dust cover shown in FIG. 1 as operatively installed on a printed circuit board with a powered device.

FIG. 2b is a front cross sectional view illustrating the dust cover shown in FIG. 1 as operatively installed on a printed circuit board with a powered device.

FIG. 3 is an isometric view illustrating a further embodiment of a dust cover in accordance with the present disclosure.

FIG. 4 is a side cross sectional view illustrating a further embodiment of a dust cover in accordance with the present disclosure.

### DETAILED DESCRIPTION

A dust cover for mitigating electrical arcing between the leads of electrically powered devices in welding machines in accordance with the present disclosure will now be described more fully with reference to the accompanying drawings, in which preferred embodiments of the dust cover are presented. The dust cover, however, may be embodied in many different forms and should not be construed as being limited to the embodiments set forth herein. Rather, these embodiments are provided so that this disclosure will be thorough and complete, and will fully convey the scope of the dust cover to those skilled in the art. In the drawings, like numbers refer to like elements throughout unless otherwise noted.

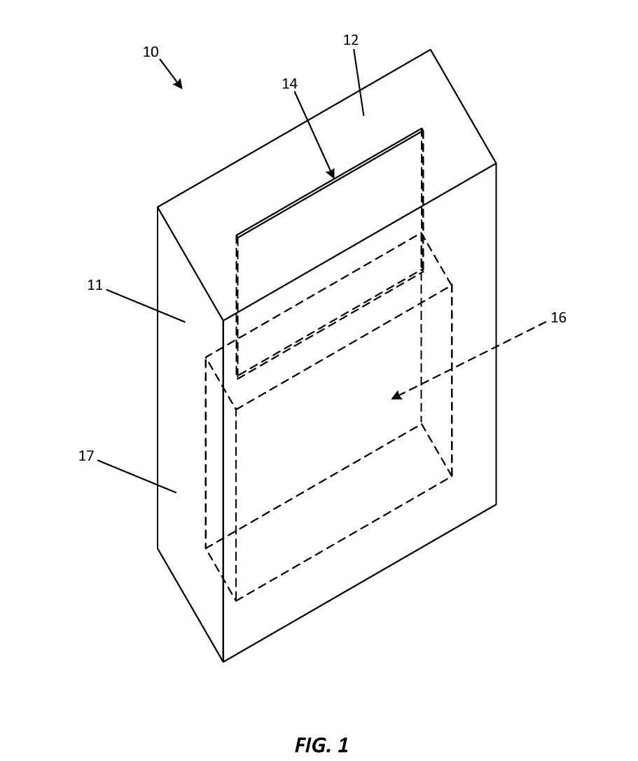

Referring to FIG. 1, an isometric view of a dust cover 10 in accordance with an exemplary embodiment of the present disclosure is shown. The dust cover 10 may be a generally rectangular, unitary body formed an elastic, resilient, and electrically-insulating material, such as rubber, silicone, plastic, or various composite materials. A closed top portion 11 of the dust cover 10 may have an elongated slit 14 formed therethrough. The slit 14 may extend vertically from an upper surface 12 of the dust cover 10 to a hollow interior chamber 16 defined by an open bottom portion 17 the dust cover 10.

Since the dust cover 10 is formed of an elastic, resilient material, the slit 14 may be formed in the dust cover 10 without removing any material from the dust cover 10. For example, the slit 14 may be cut into the dust cover 10 with a knife, whereby the material surrounding the slit 14 may be forced apart as the knife passes through the material. The material may rebound after the knife is withdrawn, thereby effectively sealing the slit 14 such that there is no gap left in the material surrounding the slit 14. The advantage conferred by this “self-sealing” characteristic of the slit 14 will be described in greater detail below.

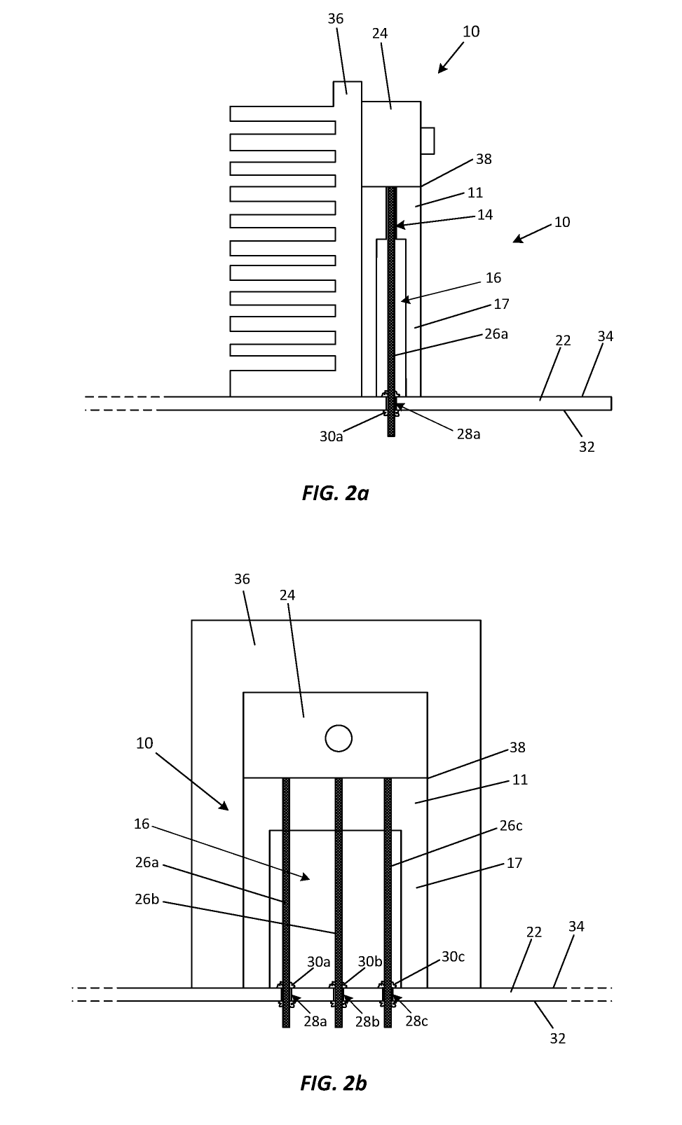

Referring to FIGS. 2a and 2b, right-side and front cross sectional views of the dust cover 10 are shown, respectively, with the dust cover 10 operatively mounted on a printed circuit board (PCB) 22. Particularly, the dust cover 10 may be vertically interposed between an electrically powered device 24 (e.g., a component of welding machine) and the PCB 22 with electrical leads 26a, 26b, 26c of the powered device 24 extending through the slit 14 and interior chamber 16 of the dust cover 10 and through corresponding apertures 28a, 28b, 28c in the PCB 22. The electrical leads 26a, 26b, 26c may be connected to the PCB 22 in electrical communication with corresponding electrical traces (not shown) on the PCB 22 with solder 30a, 30b, 30c. During application of the solder 30a, 30b, 30c (i.e., during installation of the powered device 24 on the PCB 22), the interior chamber 16 of the dust cover 10 may provide space for the solder 30a, 30b, 30c to flow from the backside 32 of the PCB 22 (where the solder is applied) through the apertures 28a, 28b, 28c and onto the front side 34 of the PCB 22, thereby providing robust electrical connections between the electrical leads 26a, 26b, 26c and their respective traces on the front side 34 of the PCB 22. The powered device 24 and the dust cover 10 may abut a heat sink 36 that may be provided for dissipating heat emitted by the powered device 26.

The uncompressed height of the dust cover 10 may be slightly greater than the vertical distance between a bottom surface 38 of the powered device 24 and the front side 34 of the PCB 22. Thus, when the powered device 24 and the dust cover 10 are operatively installed on the PCB 22 as shown in FIGS. 2a and 2b, the dust cover 10 may be compressed between the powered device 24 and the PCB 22. The dust cover 10 may forcibly engage the bottom surface 38 of the powered device 24 and the front side 34 of the PCB 22, thereby establishing tight seals between the dust cover 10 and the powered device 24 and between the dust cover 10 and the PCB 22. Metallic dust and other particulate that may be present in the environment surrounding the powered device 24 and the dust cover 10 are thereby prevented from entering the dust cover 10 and accumulating between the electrical leads 26a, 26b, 26c, thereby mitigating electrical arcing between the electrical leads 26a, 26b, 26c. Additionally, due to the elasticity of the material from which the dust cover 10 is formed, the portions of the dust cover 10 adjacent the electrical leads 26a, 26b, 26c may conformingly envelope the electrical leads 26a, 26b, 26c, and the portions of the slit 14 extending between the electrical leads 26a, 26b, 26c may be tightly sealed together, thereby eliminating any gaps in the dust cover 10 through which particulate could enter the interior chamber 16.

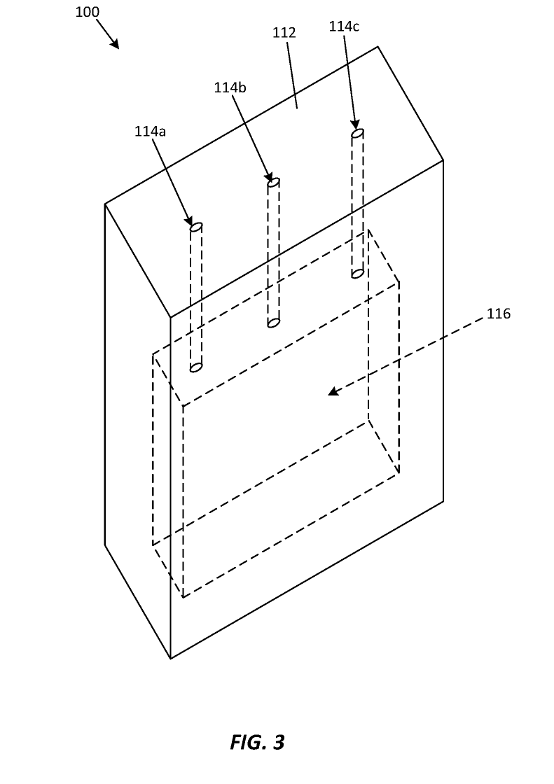

Referring to FIG. 3, an isometric view illustrating a further embodiment of a dust cover 100 in accordance with the present disclosure is shown. The dust cover 100 may be substantially similar to the dust cover 10 described above, having a generally rectangular shape and being formed of an elastic, resilient, and electrically-insulating material. However, instead of having a single slit extending vertically from an upper surface 112 to a hollow interior chamber 116 of the dust cover 100, the dust cover 100 may be provided with a plurality of discrete, laterally-spaced passageways (e.g., holes or slits) 114a, 114b, 114c extending vertically from the upper surface 112 to the hollow interior chamber 116. Each of the passageways 114a, 114b, 114c may accept a corresponding electrical lead of a powered device (not shown). Due to the elasticity of the material from which the dust cover 100 is formed, the portions of the dust cover 100 adjacent the electrical leads may conformingly envelope the electrical leads, thereby eliminating any gaps between the dust cover 100 and the electrical leads through which particulate could enter the interior chamber 116. Electrical arcing between the electrical leads that could result from the accumulation of particulate therebetween is thereby mitigated.

Unlike the dust cover 10 described above, the material of the dust cover 100 is entirely solid and contiguous between the passageways 114a, 114b, 114c, which may provide a more effective barrier to the entry of particulate relative to the slit 14 of the dust cover 10. While the dust cover 100 is shown as having 3 passageways 114a, 114b, 114c, it is contemplated that the dust cover 100 can be provided with a greater or fewer number of passageways to accommodate a corresponding number of electrical leads of a particular powered device.

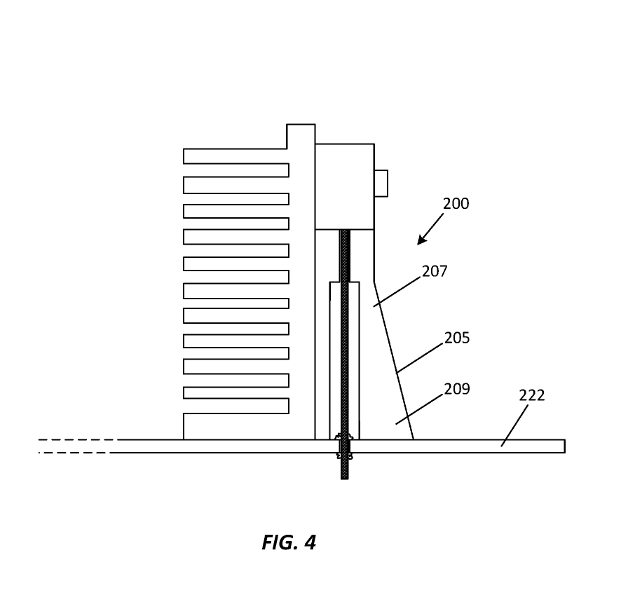

Referring to FIG. 4, a cross-sectional side view illustrating a further embodiment of a dust cover 200 in accordance with the present disclosure is shown. The dust cover 200 may be substantially similar to the dust covers 10, 100 described above, but may be provided with a tapered side wall 205 bounding a hollow interior chamber 216, the side wall 205 having a relatively thicker thinner upper end 207 and a relatively thicker lower end 209. The thicker lower end 207 of the side wall 205 may provide the base of the dust cover 200 with a greater amount of surface-to-surface contact with the PCB 222 relative to the dust covers 10, 100 described above, which have relatively thinner, straight side walls bounding their respective interior chambers 16, 116. The thicker lower end 207 may therefore provide the dust cover 200 with a greater amount of stability and with a more effective seal between the dust cover 200 and the PCB 222 relative to the front wall portions of the dust covers 10, 100 described above.

As used herein, an element or step recited in the singular and proceeded with the word “a” or “an” should be understood as not excluding plural elements or steps, unless such exclusion is explicitly recited. Furthermore, references to “one embodiment” of the present disclosure are not intended to be interpreted as excluding the existence of additional embodiments that also incorporate the recited features.

While the present disclosure makes reference to certain embodiments, numerous modifications, alterations and changes to the described embodiments are possible without departing from the sphere and scope of the present disclosure, as defined in the appended claim(s). Accordingly, it is intended that the present disclosure not be limited to the described embodiments, but that it has the full scope defined by the language of the following claims, and equivalents thereof.

1. A dust cover for mitigating electrical arcing between electrical leads of a powered device in association with a welding device, the dust cover comprising:
a unitary body formed of an elastic, electrically insulating material,
the unitary body having:
a closed top portion,
an open bottom portion,
a hollow interior chamber extending from the open bottom portion, and
a slit formed in the closed top portion for passing the electrical leads therethrough,
wherein the slit is in communication with the hollow interior chamber.

2. The dust cover of claim 1, wherein the dust cover has a generally rectangular shape.

3. The dust cover of claim 1, wherein the dust cover is made from one of a rubber, a silicone, or a plastic.

4. The dust cover of claim 1, wherein the slit extends from an upper surface of the dust cover to the hollow interior chamber.

5. The dust cover of claim 1, wherein the open bottom portion of the dust cover is operatively mounted onto a printed circuit board (PCB).

6. The dust cover of claim 5, wherein the dust cover is positioned between the powered device and the PCB.

7. The dust cover of claim 6, wherein an uncompressed height of the dust cover is greater than a vertical distance between a bottom surface of the powered device and a front side of the PCB so that the dust cover is compressed between the powered device and the PCB.

8. The dust cover of claim 7, wherein the closed top portion of the dust cover is pressed against the bottom surface of the powered device and the front side of the PCB thereby establishing a seal between the dust cover and the powered device and between the dust cover and the PCB.

9. The dust cover of claim 5, wherein the electrical leads extend from the PCB through the open bottom portion, the hollow interior chamber, and the slit for connecting to the powered device.

10. The dust cover of claim 9, wherein the electrical leads extend through apertures formed in the PCB.

11. The dust cover of claim 1, wherein the slit is self-sealing.

12. The dust cover of claim 1, wherein the slit is formed by cutting the elastic, electrically insulating material.

13. The dust cover of claim 1, further comprising a tapered side wall having an upper end and, a lower end adjacent the open bottom portion, wherein the lower end has a thickness that is greater than a thickness of the upper end.

14. The dust cover of claim 13, wherein the lower end adjacent the open bottom portion provides for an increased area for contacting a printed circuit board (PCB).

15. A dust cover for mitigating electrical arcing between electrical leads of a powered device in association with a welding device, the dust cover comprising:
a unitary body formed of an elastic, electrically insulating material,
the unitary body having:
a closed top portion,
an open bottom portion,
a hollow interior chamber extending from the open bottom portion, and
a plurality of discrete, spaced-apart passageways for passing the electrical leads therethrough, the plurality of discrete,
wherein the spaced-apart passageways are in communication with the hollow interior chamber.

16. The dust cover of claim 15, wherein the dust cover has a generally rectangular shape.

17. The dust cover of claim 15, wherein the dust cover is made from one of a rubber, a silicone, or a plastic.

18. The dust cover of claim 15, wherein the plurality of discrete, spaced-apart passageways extending from an upper surface of the dust cover to the hollow interior chamber.

19. The dust cover of claim 15, wherein the open bottom portion of the dust cover is operatively mounted onto a printed circuit board (PCB) so that the dust cover is positioned between the powered device and the PCB.

20. The dust cover of claim 19, wherein an uncompressed height of the dust cover is greater than a vertical distance between a bottom surface of the powered device and a front side of the PCB so that the dust cover is compressed between the powered device and the PCB.

21. The dust cover of claim 20, wherein the closed top portion of the dust cover is pressed against the bottom surface of the powered device and the front side of the PCB thereby establishing a tight seal between the dust cover and the powered device and between the dust cover and the PCB.

22. The dust cover of claim 19, wherein the electrical leads extend from the PCB through the open bottom portion, the hollow interior chamber, and the slit for connecting to the powered device.

23. The dust cover of claim 15, further comprising a tapered side wall having an upper end, and a lower end adjacent the open bottom portion, wherein the lower end has a thickness that is greater than a thickness of the upper end.

24. The dust cover of claim 23, wherein the lower end adjacent the open bottom portion provides for an increased area for contacting a printed circuit board (PCB).
